(19) United States
(12) Patent Application Publication
(10) Pub. No.: US 2026/0177616 A1
(43) Pub. Date: Jun. 25, 2026

(54) SEMICONDUCTOR CONTROL DEVICE

(71) Applicant: Renesas Electronics Corporation, Tokyo (JP)

(72) Inventor: Frank Guenter HANSEN, Dusseldorf (DE)

(21) Appl. No.: 19/365,640

(22) Filed: Oct. 22, 2025

(30) Foreign Application Priority Data
Dec. 20, 2024 (DE) 10 2024 139 147.2

(51) Int. Cl. G01R 31/3187

(52) U.S. Cl. CPC G01R 31/3187

(57) ABSTRACT

To provide a failure detection circuit for detecting abnormality within a semiconductor device that operates in synchronization with a clock signal, by detecting a signal path delay in the semiconductor device with respect to the clock signal. The failure detection circuit comprises a first flip-flop element configured to receive a first input data signal and to provide a first output data signal according to the first input data signal in response to the clock signal. The failure detection circuit also comprises a second flip-flop element configured to receive a second input data signal and to provide a second output data signal according to the second input data signal in response to the clock signal.

### CROSS-REFERENCE TO RELATED APPLICATIONS

The disclosure of German Patent Application No. 10 2024 139 147.2 filed on Dec. 20, 2024, including the specification, drawings and abstract is incorporated herein by reference in its entirety.

### BACKGROUND

The present document relates to a semiconductor device. In particular, the present document relates to a circuit and method for controlling function of a semiconductor device such as an integrated circuit (IC) semiconductor chip.

Semiconductor devices that contain a whole system on one chip (i.e., SoC) allow for miniaturization of electronic products and reduction of product cost by gathering semiconductor elements of different functions into one chip. Examples of SoC devices include Application-Specific Integrated Circuits (ASICs) that combine several different circuits all on one chip to allow custom programmability to combine several related functions that jointly carry out a specific overall task. On the other hand, Field Programmable Gate Arrays (FPGAs) provide flexibility and rapid prototyping through reconfigurable logic gates and programming capabilities.

Typically, SoC chips are fabricated using metal-oxide-semiconductor (MOS) technology, and, therefore, factors such as process corners, voltage, aging and/or temperature may influence the behavior of the SoC device. For example, thermal effects during device operation, and/or shifting of a threshold voltage of a transistor due to aging may increase the risk of possibly catastrophic failure of a SOC device, thereby degrading functionality/performance of the SoC device. It has also to be noted that unanticipated failures in semiconductor devices will cause system downtime in electrical systems.

To cope with these problems, process detection, voltage monitors and/or temperature sensors are additionally required for a semiconductor device to monitor its health over lifetime of the device, in order to predict failures and alert users of the need for service, prior to a catastrophic failure event. In general, device failure can be predicted by monitoring (e.g., using a sensor) physical or electrical characteristics of a semiconductor device, such as devices' ON-resistances, gate leakage currents, drain-source leakage currents, and devices' parasitic capacitances, which can be quantified and monitored by measurements of variation in voltage and current. However, measurements of certain physical parameters of a semiconductor device may not be reliable due to their dependence on a device temperature and may need to be conducted by monitoring systems which rely on high sensor complexity to achieve measurements of fast changing electrical variables. On the other hand, existing approaches of fault detection for a semiconductor device based on a temperature sensor do not provide sufficient resolution, and additional calibration may be necessary during a testing phase.

Thus, there is a need for a simple fault-detection approach to increase reliability and safety of a semiconductor device. Accordingly, the present document is directed at the technical problem of providing a simple and accurate silicon function control scheme/approach for monitoring failures taking place within a semiconductor device.

### SUMMARY

The present document is therefore directed at providing an improved silicon function control scheme/approach for monitoring failures within a semiconductor device (e.g., a SoC device such as an ASIC). Especially, an improved silicon function control circuit and design flow are provided to enhance existing measures to ensure correct silicon behavior of a SoC device by using digital standard cells.

According to an aspect, there is provided a failure detection circuit for detecting abnormality within a semiconductor device. In particular, the semiconductor device may operate in synchronization with a clock signal. Specifically, the failure detection circuit may detect the abnormality by observing/detecting a signal path delay in the semiconductor device with respect to the clock signal. In detail, the failure detection circuit comprises a first flip-flop element configured to receive a first input data signal and to provide a first output data signal according to the first input data signal in response to the clock signal. Also, the failure detection circuit comprises a second flip-flop element configured to receive a second input data signal and to provide a second output data signal according to the second input data signal in response to the clock signal.

Besides, the failure detection circuit further comprises a delay unit that is coupled between the first flip-flop element and the second flip-flop element, and that is configured to receive the first output data signal from the first flip-flop element and to provide the second input data signal as a delayed version of the first output data signal to the second flip-flop element. According to the disclosure of the present document, under normal operating conditions, the second input data signal is delayed by a predefined number of clock cycles of the clock signal with respect to the first output data signal. For example, the second input data signal may be delayed by a the path delay of a predefined number of logic gates with respect to the first output data signal.

Configured as above, by detecting/observing an increase in the delay provided by the delay unit, the proposed failure detection circuit can monitor precisely the abnormality within the semiconductor device, thereby providing an efficient and reliable silicon function control means to ensure the functional safety of the semiconductor device.

In some embodiments, the second input data signal may be delayed by substantially one clock cycle of the clock signal, or by an amount of time slightly shorter than one clock cycle of the clock signal with respect to the first output data signal. In this way, the circuit does not trigger abnormality detection under normal operating conditions.

In some embodiments, the delay unit may comprise a plurality of logic elements connected in cascade between the first flip-flop element and the second flip-flop element. In particular, the plurality of logic elements may be configured to provide the signal path delay to create a delay in time of substantially one clock cycle of the clock signal between the first output data signal and the second input data signal. Additionally, the plurality of logic elements may also comprise a plurality of AND gates connected in cascade, having a common input port as an input port of the delay unit to receive the first output data signal from the first flip-flop element.

In some embodiments, the second input data signal may be provided to the second flip-flop element from an output port of the last AND gate in the cascade as an output port of the delay unit. Optionally, the delay in time between the first output data signal and the second input data signal may be dependent on a number of the logic elements.

In some embodiments, the second flip-flop element may be configured to feed the second output data signal back to the first flip-flop element.

In some embodiments, the first flip-flop element may comprise a first data input port configured to receive the first input data signal and a first data output port configured to provide the first output data signal. Similarly, the second flip-flop element may comprise a second data input port configured to receive the second input data signal and a second data output port configured to provide the second output data signal. In addition, the circuit may further comprise an inverter coupled between the second data output port and the first data input port to feed the second output data signal back to the first flip-flop element. In this case, optionally, the first data output port may be coupled to an input port of the delay unit and the second data input port may be coupled to an output port of the delay unit.

In some embodiments, the failure detection circuit may further comprise a fault detection unit configured to generate an interrupt signal indicative of abnormality within the semiconductor device based on the first output data signal and the second output data signal.

In some embodiments, the fault detection unit may comprise a detection flip-flop element configured to receive the first output data signal and to provide a detection output data signal from the first output data signal. Besides, the fault detection unit may also comprise an XOR gate coupled to the detection flip-flop element and the second flip-flop element. In particular, the XOR gate may be configured to compare the detection output data signal and the second output data signal and to output a logic value according to a result of the comparison.

In some embodiments, the fault detection unit may further comprise a second detection flip-flop element coupled to the XOR gate and configured to generate the interrupt signal based on the output logic value.

In some embodiments, the interrupt signal may be generated in response to a change of the output logic value to 1 caused by a missing sample between the first output data signal and the second output data signal.

In some embodiments, the abnormality within a semiconductor device may comprise excessive temperature/voltage deviation from a normal temperature/voltage for operating the semiconductor device, and/or aging of the semiconductor device.

Configured as above, the present document proposes for a semiconductor device a failure detection circuit containing a chain of digital standard cells to control correct timing function and avoid malfunction within the semiconductor device. It is further appreciated that the proposed failure detection circuit may be used in any SoC devices, since it creates an intentional signal path delay out of standard logic gates, which is usable in any technology by simple adaption to the available standard cells.

According to a further aspect, there is provided a semiconductor device configured to operate in synchronization with a clock signal. The semiconductor device may have a signal path delay with respect to the clock signal for abnormality detection.

Specifically, the semiconductor device comprises a functional logic unit comprising a plurality of functional logic elements configured to perform logic functions of the semiconductor device in synchronization with the clock signal. In particular, a signal timing path between any two of the functional logic elements is shorter than one clock cycle of the clock signal with at least an additional margin.

In addition, the semiconductor device also comprises a function control unit comprising a failure detection circuit configured to detect the signal path delay caused by abnormality within the semiconductor device with respect to the clock signal according to any one of the above-described aspects and its related embodiments.

In some embodiments, the plurality of functional logic elements may comprise two or more functional flip-flop elements. Accordingly, the signal timing path may comprise a timing path between any two of the functional flip-flop elements. In some examples, the additional margin may be substantially 50 ps.

In some embodiments, the failure detection circuit may be configured to detect an increase of the signal path delay caused by a rising temperature and/or a dropping voltage in operation of the semiconductor device, and/or aging of the semiconductor device.

Configured as above, the present document proposes a simple failure detection approach as silicon function control in a semiconductor device. The proposed approach can be an enhancement to existing measures like voltage or temperature monitoring by just using standard (logic) cells.

According to a further aspect, there is provided a method for detecting abnormality within a semiconductor device. In particular, the semiconductor device may operate in synchronization with a clock signal. Thus, the abnormality may be detected by detecting/observing a signal path delay in the semiconductor device with respect to the clock signal.

According to the disclosure of the present document, the method comprises receiving a first input data signal at the first flip-flop element and a second input data signal at the second flip-flop element. The method further comprises providing, by the first flip-flop element, a first output data signal according to the first input data signal in response to the clock signal. Also, the method comprises delaying, under normal operating conditions, the first output data signal by a predefined number of clock cycles of the clock signal as the second input data signal. In particular, the predefined number of clock cycles of the clock signal as a delay between the first output data signal and the second input data signal may correspond to the signal path delay attainable via a predefined number of logic gates. For example, under normal operating conditions, the method may comprise delaying the first output data signal by the path delay of a predefined number of logic gates as the second input data signal.

Furthermore, the method comprises providing, by the second flip-flop element, a second output data signal according to the second input data signal. In addition, the method also comprises determining a change in the delay between the first output data signal and the second input data signal.

In some embodiments, the predefined number of clock cycles of the clock signal may be substantially one clock cycle of the clock signal, such that abnormality detection is not triggered under normal operating conditions.

In some embodiments, the method may further comprise adjusting a delay in time between the first output data signal and the second input data signal by applying a plurality of logic elements to the first output data signal. In particular, the delay in time of substantially one clock cycle of the clock signal may be determined based on a number of the logic elements.

In some embodiments, the second output data signal may be provided to the first flip-flop element as the first input data signal. Optionally, the method may further comprise inverting the second output data signal prior to providing to the first flip-flop element.

In some embodiments, determining a change in the delay between the first output data signal and the second input data signal may further comprise providing a detection output data signal from the first output data signal and comparing the detection output data signal and the second output data signal using an XOR operation.

In some embodiments, the method may further comprise generating, in response to an increase in a delay between the first output data signal and the second input data signal indicated by an output logic value of the XOR operation, an interrupt signal indicative of abnormality within the semiconductor device.

In some embodiments, the interrupt signal may be generated in response to a change of the output logic value to 1 caused by a missing sample between the first output data signal and the second output data signal. Optionally, the interrupt signal may be indicative of a rising temperature and/or a dropping voltage in operation of the semiconductor device, and/or aging of the semiconductor device.

Configured as above, the present document proposes a simple fault-detection method for monitoring failures taking place within a semiconductor device, in order to increase reliability and safety of the semiconductor device. Accordingly, by applying the method as proposed in the present document, the functional health of a SoC device in an operating system can be monitored with an enhanced reliability and accuracy. In particular, the operating system is enabled to deactivate (or switch off) certain functions in case of necessity according to the monitored result as indicated by e.g., an interrupt signal.

It should be noted that the methods and systems including its preferred embodiments as outlined in the present document may be used stand-alone or in combination with the other methods and systems disclosed in this document. In addition, the features outlined in the context of a system are also applicable to a corresponding method. Furthermore, all aspects of the methods and systems outlined in the present document may be arbitrarily combined. In particular, the features of the claims may be combined with one another in an arbitrary manner.

In the present document, the term “couple” or “coupled” refers to elements being in electrical communication with each other, whether directly connected e.g., via wires, or in some other manner.

### BRIEF DESCRIPTION OF THE DRAWINGS

FIG. 1 is a schematic illustration of an example failure detection circuit 100 for detecting abnormality within a semiconductor device according to present embodiments.

FIG. 2 shows a comparison of the key signals in an exemplary failure detection circuit 100 including a delay unit 103 according to the present embodiments.

FIG. 3 is a schematic illustration of an example failure detection circuit 100 including a fault detection unit 300 according to the present embodiments.

FIG. 4 is a schematic illustration of an example semiconductor device 400 employing the proposed failure detection circuit 100 for detecting abnormality within the semiconductor device 400 according to the present embodiments.

FIG. 5 shows a comparison of timing path delays between the logic components/elements within an exemplary semiconductor device 400 with respect to the clock signal according to the present embodiments.

FIG. 6 shows a flow chart of an example method 600 for detecting abnormality within a semiconductor device (e.g., the semiconductor device 400) according to the present embodiments.

### DETAILED DESCRIPTION

As indicated above, the present document is directed at providing an improved silicon function control scheme/approach for monitoring failures within a semiconductor device (e.g., ASICs). Specifically, the present document proposes an improved silicon function control circuit and design flow to enhance existing measures to ensure correct silicon behavior of a SoC device by using digital standard cells.

During a chip creation process timing paths between circuit components/elements may be fixed according to the specified signoff conditions for the related process. According to the disclosure of the present document, it is proposed to (intentionally) create one or more artificial detection paths for detecting/monitoring a failure/abnormality within a chip/device in addition to functional timing paths that may be fixed with a certain margin (e.g., 50 ps by an additional uncertainty setting). Especially, it is proposed that some of the artificially created critical paths (e.g., one or more detection paths created for performing silicon function control) may be realized with substantially no margin, e.g., 5 ps which is much shorter than for the other functional timing paths.

According to the embodiments provided in the present document, the proposed silicon function control scheme may be implemented by, for example, a chain of digital standard cells, such as AND gates. The chain of these gates may be used to create a certain delay between logic elements (e.g., between two flipflops) that exactly meets the setup timing requirement for a connected clock without margin, or substantially meets the setup timing requirement for the connected clock. For example, if the desired frequency of a connected clock is 100 MHz, a corresponding path delay may be about 10 ns (i.e., one clock cycle), which may be used for detecting a delay increase due to any circumstance, such as device aging, low voltage and/or high temperature. In this way, “failure detectors” of such type with adaption for desired clock speeds (i.e., desired operating frequencies of the clock) could be placed at several places on a die for one or more clocks, for example, to detect/monitor a failure/abnormality within a semiconductor device.

It is further appreciated that, by applying the measure/approach proposed in the present document, the functional health of a SoC device in an operating system can be monitored with an enhanced reliability and accuracy. Furthermore, based on the result of the monitoring, the operating system is enabled to shutdown (switch off) certain functions in case of necessity, which can be indicated by an interrupt signal generated in accordance with the result.

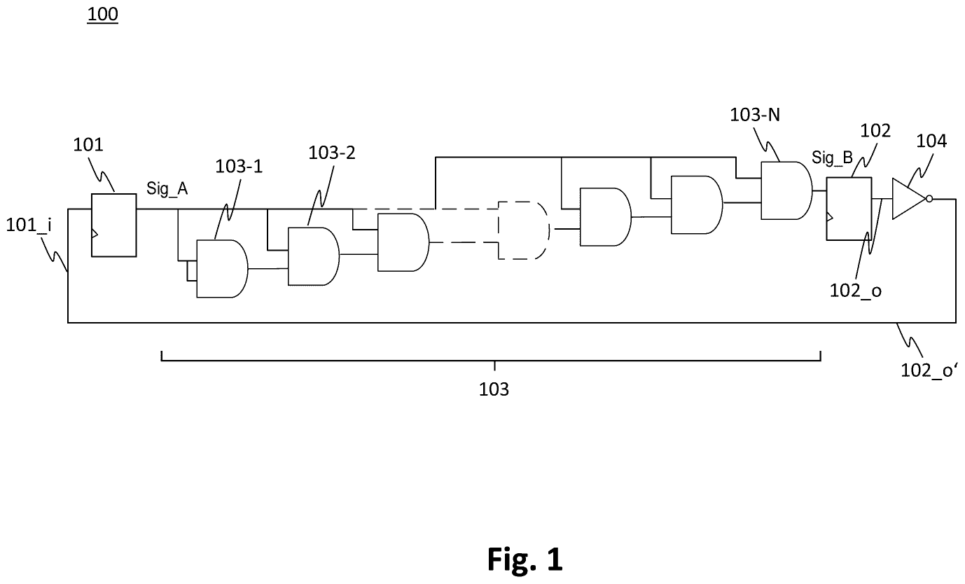

FIG. 1 schematically illustrates an example failure detection circuit 100 for detecting abnormality within a semiconductor device according to embodiments of the present document. In particular, the semiconductor device (e.g., ASICs) may operate in synchronization with a clock signal (not shown). Specifically, the circuit 100 may detect/monitor a failure/abnormality within a semiconductor device by observing or detecting a signal path delay in the semiconductor device with respect to the clock signal, especially, by observing or detecting an increase/decrease in the signal path delay. As shown in FIG. 1, the circuit 100 may include a first flip-flop element 101, a second flip-flop element 102, and a delay unit 103 coupled between the first flip-flop element 101 and the second flip-flop element 102.

In detail, the first flip-flop element 101 may be configured to receive a first input data signal 101_i and to provide a first output data signal Sig_A according to the first input data signal 101_i in response to the clock signal, and the second flip-flop element 102 may be configured to receive a second input data signal Sig_B and to provide a second output data signal 102_o according to the second input data signal Sig_B in response to the clock signal. Moreover, the delay unit 103 may be configured to receive the first output data signal Sig_A from the first flip-flop element 101 and to provide the second input data signal Sig_B as a delayed version of the first output data signal Sig_A to the second flip-flop element 102.

It should be noted that, under normal operating conditions, the second input data signal Sig_B may be delayed by a predefined number of clock cycles of the clock signal with respect to the first output data signal Sig_A. For example, the second input data signal Sig_B may be delayed by substantially one clock cycle of the clock signal, or by an amount of time slightly shorter than one clock cycle of the clock signal (e.g., 5 ps) with respect to the first output data signal Sig_A, such that the circuit 100 does not trigger abnormality detection under normal operating conditions.

As mentioned above, the circuit 100 as proposed in the present document may include a chain of digital standard cells/logic elements (e.g., AND gates) as the delay unit 103 to provide a delay path between the first flip-flop element 101 and the second flip-flop element 102. As illustrated in the example of FIG. 1, the delay unit 103 may include a plurality of AND gates 103-1, 103-2, . . . , 103-N connected in cascade between the first flip-flop element 101 and the second flip-flop element 102, which may be used to create a delay in time of substantially one clock cycle of the clock signal between the first output data signal Sig_A and the second input data signal Sig_B, in order to meet exactly the setup timing requirement for the clock signal without margin, or to meet substantially the setup timing requirement for the clock signal.

For example, if the desired frequency of the clock signal is 100 MHz, a corresponding path delay created by the delay unit 103 may be about 10 ns (i.e., one clock cycle) to detect a delay increase due to abnormality e.g., device aging, low voltage and/or high temperature within the semiconductor device. Specifically, the abnormality within a semiconductor device may include excessive temperature/voltage deviation from a normal temperature/voltage for operating the semiconductor device, and/or aging of the semiconductor device.

In the example of FIG. 1, the plurality of cascadingly connected AND gates 103-1, 103-2, . . . , 103-N may have a common input port as an input port of the delay unit 103 to receive the first output data signal Sig_A from the first flip-flop element 101. In addition, the second input data signal Sig_B may be provided to the second flip-flop element 102 from an output port of the last AND gate 103-N in the cascade as an output port of the delay unit 103. It should be noted that the created delay in time between the first output data signal Sig_A and the second input data signal Sig_B may depend on the number of the AND gates, based on which a suitable number of AND gates may be applied for designing the failure detection circuit 100.

It is noted that the aforementioned exemplary implementation of the failure detection circuit 100 using cascadingly connected AND gates as the logic elements for the delay unit 103 is a non-limiting example for creating an appropriate time delay between the first flip-flop element 101 and the second flip-flop element 102 for meeting (exactly or substantially) the setup timing requirement for the clock signal. It is appreciated that other types of logic elements/cells and combinations thereof, and/or any number of logic elements are feasible and within the scope of the disclosure in the present document.

As further indicated by FIG. 1, the second flip-flop element 102 may be configured to feed the second output data signal 102_o back to the first flip-flop element 101. In the specific example, the first flip-flop element 101 may have a first data input port configured to receive the first input data signal 101_i and a first data output port configured to provide the first output data signal Sig_A. Also, the second flip-flop element 102 may have a second data input port configured to receive the second input data signal Sig_B and a second data output port configured to provide the second output data signal 102_o. In addition, an inverter 104 may further be coupled between the second data output port and the first data input port to feed the second output data signal 102_o back to the first flip-flop element 101. As will be understood by the skilled person in the art, the inverter 104 may provide an inverted second output data signal 102_o′ as the first input data signal 101_i to the first flip-flop element 101. In the above case, the first data output port of the first flip-flop element 101 may be coupled to an input port of the delay unit 103 and the second data input port of the second flip-flop element 102 may be coupled to an output port of the delay unit 103.

It is noted that the aforementioned exemplary implementation of the failure detection circuit 100 having connections between the flip-flop elements and the logic elements (e.g., the AND gates, the inverter, etc.) as explicitly illustrated in FIG. 1 is a non-limiting example for creating an appropriate signal (timing) path for detecting/monitoring a delay increase due to any circumstance/abnormality, such as device aging, low voltage and/or high temperature, within a semiconductor device. It is appreciated that other types of logic elements/cells and combinations thereof, any number of logic elements, and/or other ways of connections between the flip-flop elements and the logic elements are feasible and within the scope of the disclosure in the present document.

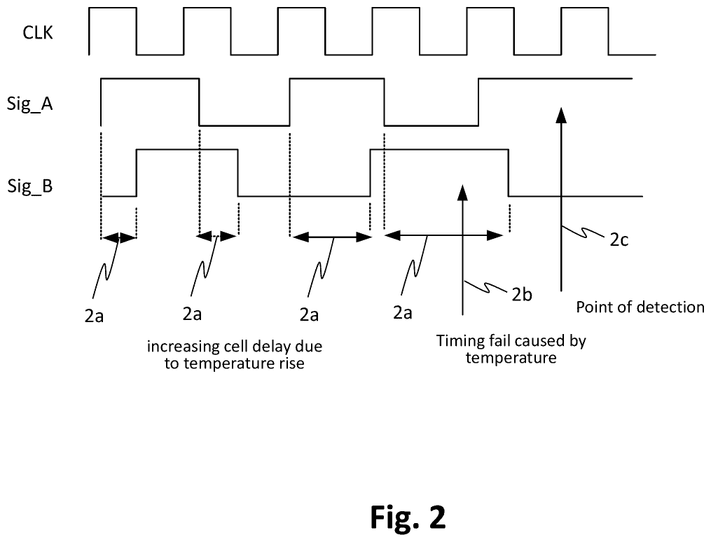

FIG. 2 schematically shows a comparison of the key signals in an exemplary failure detection circuit 100 including a delay unit 103 according to embodiments of the present document. Herein, the clock signal (as indicated by “CLK”) based on which the semiconductor device is operated is compared with the first output data signal Sig_A and the second input data signal Sig_B, with temperature rising along with time. As illustrated in FIG. 2, the first output data signal Sig_A still follows the clock signal CLK (with a small amount of a fixed time delay with respect to the clock signal), while, with the delay unit 103, the second input data signal Sig_B may lose synchronization with the clock signal CLK due to an increasing delay along a signal path between the first flip-flop element 101 and the second flip-flop element 102, which may come from an increasing cell delay introduced by a rising temperature (as indicated by 2a).

It may be observed that a significant increase in the signal path delay due to the increasing cell delay will cause timing of the second input data signal Sig_B (provided by the delay unit 103) to fail just after a few cycles (as indicated by 2b). Although FIG. 2 explicitly refers to an increasing cell delay between Sig_A and Sig_B caused by a rising temperature, it is understood that similar results may be observed with respect to an increasing cell delay caused by other abnormality within the semiconductor device (e.g., aging or decreasing voltage).

In other words, compared to the first output data signal Sig_A, the second input data signal Sig_B may have an increasing signal path delay due to accumulation of delays caused by the individual cells/logic elements constituting the delay unit 103 in case of abnormality. Thus, by creating a delay path between the flip-flop elements right at the border for meeting the timing requirement for the clock signal without margin (e.g., one clock cycle), a delay increase that reflects abnormal circumstance within the semiconductor device can be easily detected/monitored, thereby enhancing the reliability and accuracy of the proposed failure detection circuit 100.

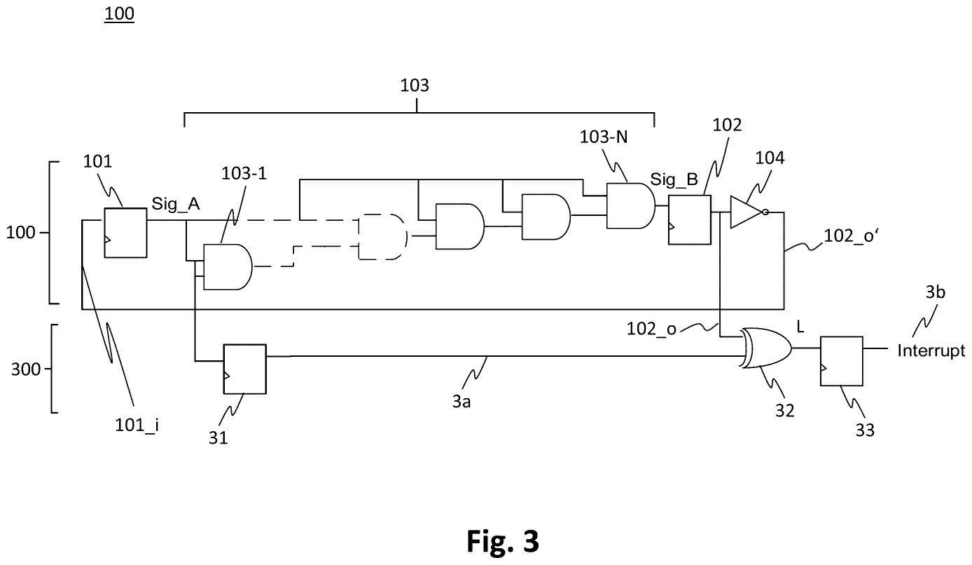

In order to detect an increasing signal path delay of the second input data signal Sig_B, the proposed failure detection circuit 100 may also include a fault detection unit 300 as illustrated in FIG. 3 according to embodiments of the present document. As shown in FIG. 3, the fault detection unit 300 may be configured to generate an interrupt signal 3b indicative of abnormality within the semiconductor device based on the first output data signal Sig_A and the second output data signal 102_o.

More specifically, the fault detection unit 300 may include a detection flip-flop element 31, and an XOR gate 32 coupled to the detection flip-flop element 31 and the second flip-flop element 102. The detection flip-flop element 31 may be configured to receive the first output data signal Sig_A and to provide a detection output data signal 3a from the first output data signal Sig_A. The XOR gate 32 may be configured to compare the detection output data signal 3a and the second output data signal 102_o, and to output a logic value L according to a result of the comparison.

In addition, the fault detection unit 300 may further include a second detection flip-flop element 33 coupled to the XOR gate 32. The second detection flip-flop element 33 may be configured to generate the interrupt signal 3b based on the output logic value L. In particular, the interrupt signal 3b may be generated in response to a change of the output logic value L to 1 which may be caused by a missing sample between the first output data signal Sig_A and the second output data signal 102_o. Accordingly, the generation of the interrupt signal 3b can be triggered by the XOR gate 32 which compare the output 3a of the detection flip-flop element 31 with the output 102_o of the second flip-flop element 102.

It is noted that the output 3a and the output 102_o should usually have the same value when they are synchronous with each other. However, in case the second input data signal Sig_B has lost synchronization with the clock signal CLK due to an increasing cell delay introduced by a rising temperature (as indicated by 2a in FIG. 2), there will be a missing sample between the first output data signal Sig_A and the second output data signal 102_o (as a result of a significant increase in the signal path delay which leads to timing fail for Sig_B, as indicated by 2b in FIG. 2). Accordingly, the output 3a and the output 102_o may have different values/levels which then cause the interrupt signal 3b to rise. When the output 3a and the output 102_o become to have different values/levels, the output logic value L of the XOR gate 32 may change to 1, which then triggers the generation of the interrupt signal 3b.

Notably, the second detection flip-flop element 33 may generate the interrupt signal 3b after a small amount of delay as indicated by 2c in FIG. 2 (i.e., point of detection), although timing of the second input data signal Sig_B may already fail earlier as indicated by 2b in FIG. 2 (and also a missing sample between the first output data signal Sig_A and the second output data signal 102_o may already appear at point 2b). It is further appreciated that, in case of abnormality such as high temperature, low voltage and/or device aging, the (total) delay between the first flip-flop element 101 and the second flip-flop element 102 may increase, since the (individual) delay of a single gate (e.g., AND gate) may depend on, for example, temperature and/or voltage. Either low voltage or high temperature may increase the delay of a gate. In this way, it is possible to detect the existence of a problem in an efficient and reliable manner, without the need of a sensor of high complexity.

It is noted that the aforementioned exemplary implementation of the fault detection unit 300 comprising the flip-flop elements 31, 33 and the XOR gate 32 and having connections between the flip-flop elements 31, 33 and the XOR gate 32 as explicitly illustrated in FIG. 3 is a non-limiting example for generating the interrupt signal as an indication of detected abnormality in the semiconductor device. It is appreciated that other types of logic elements/cells and combinations thereof, any number of logic elements, and/or other ways of connections between the flip-flop elements and the logic elements are feasible and within the scope of the disclosure in the present document.

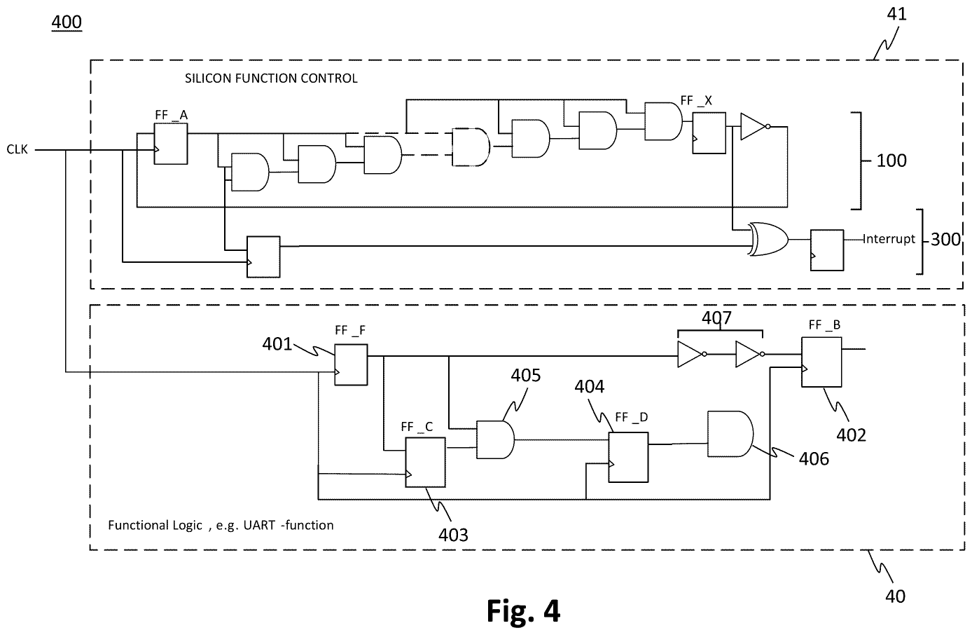

FIG. 4 schematically illustrates an example semiconductor device 400 employing the proposed failure detection circuit 100 for detecting abnormality within the semiconductor device 400 according to embodiments of the present document. As mentioned above, the semiconductor device 400 (e.g., ASICs) may operate in synchronization with a clock signal CLK. In particular, the semiconductor device 400 may have a signal path delay with respect to the clock signal CLK for abnormality detection, as described above with respect to FIGS. 1 to 3.

In detail, the semiconductor device 400 may include a functional logic unit 40 for performing functions of the semiconductor device 400, and a function control unit 41 for detecting abnormality within the semiconductor device 400. The functional logic unit 40 may include a plurality of functional logic elements 401, 402, . . . , 407 configured to perform logic functions (e.g., universal asynchronous receiver-transmitter, UART, functions) of the semiconductor device 400 in synchronization with the clock signal CLK. On the other hand, the function control unit 41 may include a failure detection circuit as illustrated by the failure detection circuit 100 in FIG. 1 or FIG. 3., which may be configured to detect the signal path delay caused by abnormality within the semiconductor device 400 with respect to the clock signal CLK. In some implementations, the failure detection circuit in the function control unit 41 of the semiconductor device 400 may also include the above-described fault detection unit 300.

Notably, in the functional logic unit 40 of the semiconductor device 400, a signal timing path between any two of the functional logic elements may be shorter than one clock cycle of the clock signal CLK with at least an additional margin (e.g., around 50 ps or slightly deviating from 50 ps). In the example of FIG. 4, among the functional logic elements, the semiconductor device 400 may include two or more functional flip-flop elements 401 (FF_F), 402 (FF_B), 403 (FF_C), 404 (FF_D). Thus, a timing path between any two of the functional flip-flop elements 401 to 404 in the functional logic unit 40 may be regarded as a signal timing path. Similar to the failure detection circuit as illustrated in FIGS. 1 and 3, the failure detection circuit in the function control unit 41 of the semiconductor device 400 may also be configured to detect an increase of the signal path delay caused by a rising temperature and/or a dropping voltage in operation of the semiconductor device 400, and/or aging of the semiconductor device 400 (i.e., the abnormality of the semiconductor device 400).

In the example shown in FIG. 4, it is desired that a signal timing path between any two functional flip-flop elements (e.g., FF_F to FF_B, FF_F to FF_C, and/or FF_F to FF_D) is shorter than the frequency-cycle time (i.e., one clock cycle), in order to meet the timing requirements in synchronous digital design. In some preferrable implementations, this requirement may be enhanced by taking into account an additional margin (e.g., 50 ps). Namely, a signal timing path between any two functional flip-flop elements may preferably be set to be shorter than the frequency-cycle time minus the additional margin, which, in practice, can be realized using Static Timing Analysis (STA) tools by e.g., adding uncertainty setting in the configuration.

On the other hand, in the function control unit 41, the (signal) timing path (as a detection path for monitoring a failure/abnormality of the device 400) between the flip-flop element FF_A (which is similar to the first flip-flop element 101 in FIG. 1) to FF_X (which is similar to the second flip-flop element 102 in FIG. 1) may be set to be just slightly less than the cycle time (i.e., one clock cycle), as indicated above in the description with respect to FIGS. 1 to 3. As explained above, this timing path may fail due to a delay increase along the path by e.g., high temperature, while other functional paths (e.g., paths from FF_F to FF_B, from FF_F to FF_C, and/or from FF_F to FF_D, etc.) still meet their requirements.

It is appreciated that the logical paths FF_F to FF_B, FF_F to FF_C, and/or FF_F to FF_D may reside in the functional logic (e.g., functional logic unit 40) of a SoC device, e.g., a universal asynchronous receiver-transmitter, UART, and the timing paths herein within the functional logic may contain a certain margin (e.g., 50 ps), so these functional logic elements can stay functional in case of a slight temperature increase. As indicated above, within the silicon function control logic of the SoC device (e.g., function control unit 41), FF_X (the second flip-flop element 102) is fed back to FF_A (the first flip-flop element 101), and if the path delay therebetween increases with temperature rise, the path delay may become longer than one clock period, and thus the signal of FF_A may not be inverted (i.e., the output of FF_A and the output of FF_X are inverted, namely, having different values/levels). By detecting this state (e.g., using the XOR gate 32 that compares the output of FF_A and the output of FF_X), it is possible to detect that the temperature has risen or voltage has dropped, or aging in the semiconductor device 400.

It is noted that the aforementioned exemplary implementation of the semiconductor device 400 including the functional logic unit 40 as explicitly illustrated in FIG. 4 and employing the failure detection circuit as explicitly illustrated by the failure detection circuit 100 in FIG. 1 and FIG. 3 for the function control unit 41 thereof is a non-limiting example for detecting and indicating abnormal circumstances within the semiconductor device. It is appreciated that other types of logic elements/cells and combinations thereof, any number of logic elements, and/or other ways of connections between the flip-flop elements and the logic elements are feasible for implementing the functional logic unit 40/function control unit 41 and within the scope of the disclosure in the present document.

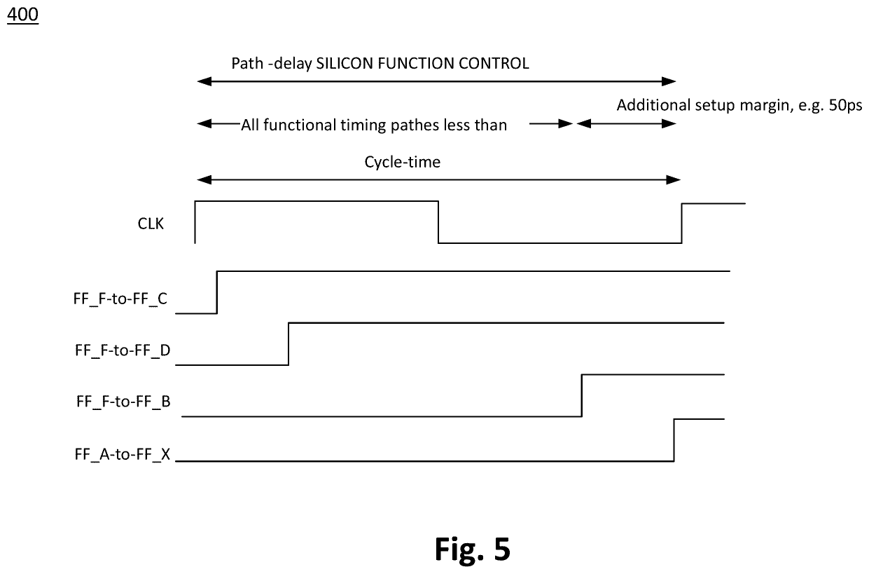

FIG. 5 schematically shows a comparison of timing path delays between the logic components/elements within an exemplary semiconductor device 400 with respect to the clock signal according to embodiments of the present document. It can be observed that the timing path delays between the functional flip-flop elements: from FF_F to FF_B, from FF_F to FF_C, and from FF_F to FF_D) are shorter than one clock cycle to meet the timing requirements in synchronous digital design, taking into account an additional margin (e.g., 50 ps). Besides, the amount of a timing path delay for a path may depend on a number of logic elements in that path. For example, the path (and the corresponding path delay) from FF_F to FF_B is considerably longer than the path from FF_F to FF_C, since the path from FF_F to FF_B contains more logic elements than the path from FF_F to FF_C. Moreover, it can be seen that the timing path delay between the function control flip-flop elements, i.e., from FF_A to FF_X, is set to substantially one clock cycle of the clock signal, as described above with respect to FIGS. 1 to 3.

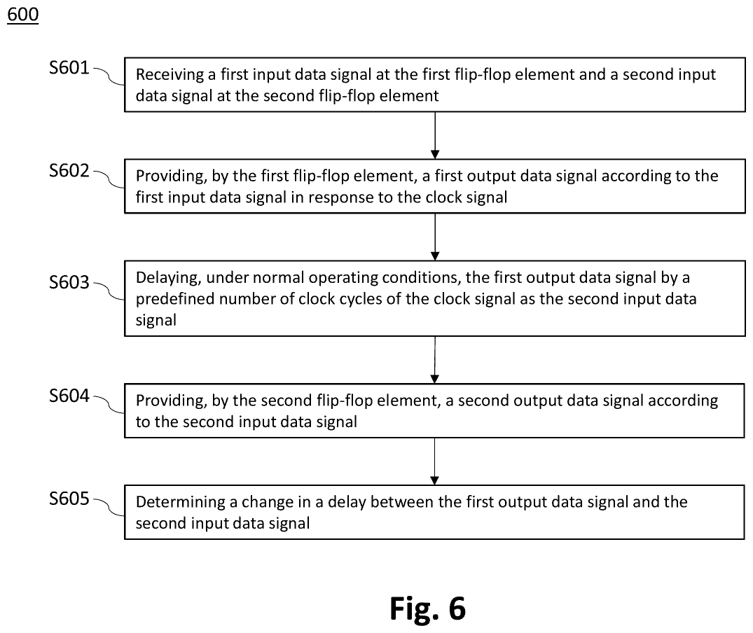

FIG. 6 shows a flow chart of an example method 600 for detecting abnormality within a semiconductor device (e.g., the semiconductor device 400) according to embodiments of the present document, wherein the semiconductor device 400 is configured to operate in synchronization with a clock signal. Besides, the abnormality within the semiconductor device may be detected/monitored by detecting/observing a signal path delay in the semiconductor device with respect to the clock signal. It is appreciated that the method 600 may be conducted by e.g., the failure detection circuit 100 as illustrated in FIGS. 1, 3 and 4.

Specifically, the method 600 comprises receiving 601 a first input data signal at the first flip-flop element and a second input data signal at the second flip-flop element. The method 600 also comprises providing 602, by the first flip-flop element, a first output data signal according to the first input data signal in response to the clock signal. In particular, the method 600 further comprises delaying 603, under normal operating conditions, the first output data signal by a predefined number of clock cycles of the clock signal as the second input data signal. In addition, the method 600 comprises providing 604, by the second flip-flop element, a second output data signal according to the second input data signal. Besides, the method 600 also comprises determining 605 a change in a delay between the first output data signal and the second input data signal. It is noted that, the predefined number of clock cycles of the clock signal as the delay between the first output data signal and the second input data signal may correspond to the signal path delay attainable via a predefined number of logic gates.

Accordingly, the proposed circuit together with its methodology implicitly takes into account the process variation, voltage, aging, temperature, and peak to peak jitter, for detecting failure/abnormality with the semiconductor device. In case of detection of a failure, an interrupt signal can be generated to highlight/indicate a circumstance that may urgently need attention by the operating system.

It is further appreciated that the proposed approach for silicon function control by just using standard cells is much simpler than using a sensor with high complexity to monitor physical or electrical characteristics of a semiconductor device. However, the proposed approach for silicon function control can also be an enhancement to the existing measures like voltage or temperature monitoring (e.g., to be applied at a calibration/testing phase) to improve the accuracy/reliability of the parameter monitoring.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiment outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A failure detection circuit for detecting abnormality within a semiconductor device that operates in synchronization with a clock signal, by observing a signal path delay in the semiconductor device with respect to the clock signal, the circuit comprising:
a first flip-flop circuit configured to receive a first input data signal and to provide a first output data signal according to the first input data signal in response to the clock signal;
a second flip-flop circuit configured to receive a second input data signal and to provide a second output data signal according to the second input data signal in response to the clock signal; and
a delay circuit coupled between the first flip-flop circuit and the second flip-flop circuit, and configured to receive the first output data signal from the first flip-flop circuit and to provide the second input data signal as a delayed version of the first output data signal to the second flip-flop circuit, wherein, under normal operating conditions, the second input data signal is delayed by a predefined number of clock cycles of the clock signal with respect to the first output data signal.

2. The circuit of claim 1, wherein the second input data signal is delayed by substantially one clock cycle of the clock signal, or by an amount of time slightly shorter than one clock cycle of the clock signal with respect to the first output data signal, such that the circuit does not trigger abnormality detection under normal operating conditions.

3. The circuit of claim 2, wherein the delay circuit comprises a plurality of logic circuits connected in cascade between the first flip-flop circuit and the second flip-flop circuit, the plurality of logic circuits configured to provide the signal path delay to create a delay in time of substantially one clock cycle of the clock signal between the first output data signal and the second input data signal.

4. The circuit of claim 3, wherein the plurality of logic circuits comprises a plurality of cascadingly connected AND gates having a common input port as an input port of the delay circuit to receive the first output data signal from the first flip-flop circuit.

5. The circuit of claim 4, wherein the second input data signal is provided to the second flip-flop circuit from an output port of the last AND gate in the cascade as an output port of the delay circuit.

6. The circuit of claim 5, wherein the delay in time between the first output data signal and the second input data signal is dependent on a number of the logic circuits.

7. The circuit of claim 6, wherein the second flip-flop circuit is configured to feed the second output data signal back to the first flip-flop circuit.

8. The circuit of claim 7, wherein the first flip-flop circuit comprises a first data input port configured to receive the first input data signal and a first data output port configured to provide the first output data signal, and the second flip-flop circuit comprises a second data input port configured to receive the second input data signal and a second data output port configured to provide the second output data signal, the circuit further comprising an inverter coupled between the second data output port and the first data input port to feed the second output data signal back to the first flip-flop circuit.

9. The circuit of claim 8, wherein the first data output port is coupled to an input port of the delay circuit and the second data input port is coupled to an output port of the delay circuit.

10. The circuit of claim 9, further comprising a fault detection circuit configured to generate an interrupt signal indicative of abnormality within the semiconductor device based on the first output data signal and the second output data signal.

11. The circuit of claim 10, wherein the fault detection circuit comprises a detection flip-flop circuit configured to receive the first output data signal and to provide a detection output data signal from the first output data signal, and an XOR gate coupled to the detection flip-flop circuit and the second flip-flop circuit, the XOR gate configured to compare the detection output data signal and the second output data signal and to output a logic value according to a result of the comparison.

12. The circuit of claim 11, the fault detection circuit further comprising a second detection flip-flop circuit coupled to the XOR gate and configured to generate the interrupt signal based on the output logic value.

13. The circuit of claim 12, wherein the interrupt signal is generated in response to a change of the output logic value to 1 caused by a missing sample between the first output data signal and the second output data signal.

14. The circuit of claim 13, wherein the abnormality within a semiconductor device comprises excessive temperature/voltage deviation from a normal temperature/voltage for operating the semiconductor device, and/or aging of the semiconductor device.

15. A method for detecting abnormality within a semiconductor device that operates in synchronization with a clock signal, by observing a signal path delay in the semiconductor device with respect to the clock signal, the method comprising:
receiving a first input data signal at the first flip-flop circuit and a second input data signal at the second flip-flop circuit;
providing, by the first flip-flop circuit, a first output data signal according to the first input data signal in response to the clock signal;
delaying, under normal operating conditions, the first output data signal by a predefined number of clock cycles of the clock signal as the second input data signal, the predefined number of clock cycles of the clock signal as a delay between the first output data signal and the second input data signal corresponding to the signal path delay attainable via a predefined number of logic gates;
providing, by the second flip-flop circuit, a second output data signal according to the second input data signal; and determining a change in the delay between the first output data signal and the second input data signal.

16. The method of claim 15, wherein the predefined number of clock cycles of the clock signal is substantially one clock cycle of the clock signal, such that abnormality detection is not triggered under normal operating conditions.

17. The method of claim 16, further comprising adjusting a delay in time between the first output data signal and the second input data signal by applying a plurality of logic circuits to the first output data signal, wherein the delay in time of substantially one clock cycle of the clock signal is determined based on a number of the logic circuits.

18. The method of claim 17, wherein the second output data signal is provided to the first flip-flop circuit as the first input data signal.

19. The method of claim 18, further comprising inverting the second output data signal prior to providing to the first flip-flop circuit.

20. The method of claim 19, wherein determining a change in the delay between the first output data signal and the second input data signal further comprises providing a detection output data signal from the first output data signal and comparing the detection output data signal and the second output data signal using an XOR operation.
